(19) United States
(12) Patent Application Publication
(10) Pub. No.: US 2023/0187576 A1
(43) Pub. Date: Jun. 15, 2023

(54) METHOD FOR MANUFACTURING INDIUM GALLIUM NITRIDE QUANTUM WELL

(71) Applicant: NATIONAL SUN YAT-SEN UNIVERSITY, Kaohsiung City (TW)

(72) Inventors: I-KAI LO, Kaohsiung City (TW); HUEI-JYUN SHIH, Kaohsiung City (TW); YING-CHIEH WANG, Kaohsiung City (TW)

(21) Appl. No.: 17/563,489

(22) Filed: Dec. 28, 2021

(30) Foreign Application Priority Data
Dec. 13, 2021 (TW) 110146564

(51) Int. Cl. H01L 33/06; H01L 33/00

(52) U.S. Cl. CPC H01L 33/06; H01L 33/0075

(57) ABSTRACT

A method for manufacturing an indium gallium nitride quantum well is disclosed. The method includes providing a substrate in a process chamber, with the substrate including a gallium nitride layer. Having the process chamber reach a process vacuum. Providing a nitrogen molecular beam in plasma state, an indium molecular beam and an aluminum molecular beam into the process chamber simultaneously, controlling a flow rate ratio of the indium molecular beam to the aluminum molecular beam, and forming an indium aluminum nitride film on the gallium nitride layer, with the flow rate ratio being 0.6, 1.0, 1.29, 1.67 or 3.0. Forming an indium gallium nitride quantum well on the indium aluminum nitride film.

### CROSS REFERENCE TO RELATED APPLICATION

The application claims the benefit of Taiwan application serial No. 110146564, filed on Dec. 13, 2021, and the entire contents of which are incorporated herein by reference.

### BACKGROUND OF THE INVENTION

### 1. Field of the Invention

The present invention generally relates to an optical semiconductor manufacturing process technology and, more particularly, to a method for manufacturing an indium gallium nitride quantum well with lattices matching to reduce lattice defects.

### 2. Description of the Related Art

Common semiconductor materials are composed of compounds with four valence electrons, while silicon (Si) as an element of group IV is a common semiconductor material adapted for mature processing technology. However, silicon has poor light-emitting characteristics. Moreover, the energy gap (band gap) of a single material can only emit light of a single wavelength. Therefore, semiconductor materials used for photoelectric components, such as lasers, light-emitting diodes, and light sensors, are selected from the III-V group compounds, including aluminum (Al), gallium (Ga), and indium (In) of group III, and nitrogen (N), phosphorus (P), arsenic (As), and stibium (Sb) of group V. By combining different elements, various sizes of energy gaps are generated, so that light of specific wavelength is emitted in accordance with the working requirement.

Conventional III-V group compound semiconductors used for optoelectronic components could have a quantum well structure. Among them, there is a lattice mismatch between the barrier of gallium nitride (GaN) or aluminum gallium nitride (AlGaN) and the potential energy well of indium gallium nitride (InGaN), resulting in the lattice defects and reduction of the internal quantum efficiency (IQE) of the component. In addition, the lattice mismatch will cause stress accumulation. When the stress in the crystal lattice exceeds its critical value, cracks will occur and thus reduce the production yield.

In light of the above problem, it is necessary to improve the conventional method for manufacturing an indium gallium nitride quantum well.

### SUMMARY OF THE INVENTION

To solve the problems mentioned above, it is therefore an objective of the present invention to provide a method for manufacturing an indium gallium nitride quantum well, which can reduce the lattice mismatch defects so as to improve the quality and internal quantum efficiency of the component.

It is another objective of the present invention to provide a method for manufacturing an indium gallium nitride quantum well, which is adapted to produce materials which can emit light of required wavelengths.

As used herein, the term “a”, “an” or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A method for manufacturing an indium gallium nitride quantum well according to an embodiment includes steps of providing a substrate in a process chamber, with the substrate including a gallium nitride layer; having the process chamber reach a process vacuum; providing a nitrogen molecular beam in plasma state, an indium molecular beam and an aluminum molecular beam into the process chamber simultaneously, controlling a flow rate ratio of the indium molecular beam to the aluminum molecular beam, and forming an indium aluminum nitride film on the gallium nitride layer, in which the flow rate ratio is 0.6, 1.0, 1.29, 1.67 or 3.0; and forming an indium gallium nitride quantum well on the indium aluminum nitride film.

Accordingly, the method for manufacturing an indium gallium nitride quantum well according to the embodiment controls the growth temperature and molecular beam flow rate in the molecular beam epitaxy system, so that the defects are reduced in the formed indium aluminum nitride film, and the quantum well efficiency of the indium gallium nitride quantum well grown subsequently is improved.

In an example, the process vacuum is between 10⁻⁶ and 10⁻¹¹ torr. Thus, before molecular beam epitaxy, the process chamber can reach an ultra-high vacuum state, ensuring the effect of avoiding contamination by air molecules resulted from impurities.

In an example, during forming the indium aluminum nitride film, the process chamber is maintained at a growth temperature of 530° C. stably, at a growth vacuum between 10⁻⁵ and 10⁻⁶ torr, and for a duration of 120 minutes. Thus, the growth conditions of the indium aluminum nitride film are provided, ensuring the effect of improving the quality of the component.

In an example, a flow rate of the nitrogen molecular beam is between 10⁻⁵ and 10⁻⁶ torr, a flow rate of the indium molecular beam is between 1.5x10⁻⁸ and 3.0x10⁻⁸ torr, and a flow rate of the aluminum molecular beam is between 1.0x10⁻⁸ and 2.5x10⁻⁸ torr. Thus, the nitrogen molecular beam is provided as plasma assistance, the indium molecular beam and the aluminum molecular beam are controlled by the flow rate ratio, ensuring the effect of adjusting the indium contents in materials of the component.

In an example, a chemical formula of the indium gallium nitride quantum well is InₓGa₁₋ₓN, a chemical formula of the indium aluminum nitride film is In_{y}Al_{1-y}N, and values of x and y are analyzed to represent indium contents in the indium gallium nitride quantum well and the indium aluminum nitride film, respectively. Thus, through the process of measuring x and y, the element composition ratios in the indium gallium nitride quantum well and the indium aluminum nitride film can be obtained, ensuring the effect of matching the lattice constant and adjusting the energy gap.

In an example, the value of x is adjusted between 13.0% to 18.7%, the value of y is adjusted between 28.9% to 33.5%, and the indium gallium nitride quantum well emits blue light. Thus, the energy gap of the material corresponds to the wavelength of 450 to 490 nm, ensuring the effects of corresponding to the required wavelength of various optoelectronic components.

In an example, the value of x is adjusted between 19.9% to 27.7%, the value of y is adjusted between 34.6% to 40.9%, and the indium gallium nitride quantum well emits green light. Thus, the energy gap of the material corresponds to the wavelength of 500 to 565 nm, ensuring the effects of corresponding to the required wavelength of various optoelectronic components.

In an example, the value of x is adjusted between 33.9% to 43.8%, the value of y is adjusted between 46.0% to 54.1%, and the indium gallium nitride quantum well emits red light. Thus, the energy gap of the material corresponds to the wavelength of 625 to 740 nm, ensuring the effects of corresponding to the required wavelength of various optoelectronic components.

### DETAILED DESCRIPTION OF THE INVENTION

A method for manufacturing an indium gallium nitride quantum well according to a preferred embodiment includes steps of providing a substrate in a vacuum chamber; providing an indium/aluminum molecular beam assisted by a nitrogen molecular beam; forming an indium aluminum nitride film on the substrate; and forming an indium gallium nitride quantum well on the indium aluminum nitride film.

The substrate includes a gallium nitride layer, which is formed on a sapphire substrate of aluminum oxide (Al₂O₃) through Metal-Organic Chemical Vapor Deposition (MOCVD). The gallium nitride layer may be a thin film with a thickness of 4.5 micrometers.

Before putting the substrate into a molecular beam epitaxy (MBE) system, clean the substrate first with solvents such as acetone, isopropanol, water, etc., and then clean the substrate with nitrogen. Sequentially convey the substrate into each chamber of the molecular beam epitaxy system for segments of vacuum process. For example, put the substrate into a load lock chamber for 4 hours at 180° C. in order to remove moisture. Then, send the substrate by a robotic arm to a buffer chamber and heat up to 550° C. in order to further remove impurities, and carry it to a process chamber of the molecular beam epitaxy system.

The process chamber is adapted to reach a process vacuum, so that the substrate is in an ultra-high vacuum state. A nitrogen molecular beam in plasma state, an indium molecular beam and an aluminum molecular beam are introduced into the process chamber simultaneously. It is preferable to control a flow rate ratio of the indium molecular beam to the aluminum molecular beam as 0.6, 1.0, 1.29, 1.67, or 3.0. The process chamber is maintained at a growth temperature of 530° C. stably, at a growth vacuum between 10⁻⁵ and 10⁻⁶ torr, and for a duration of 120 minutes in order to form the indium aluminum nitride film on the gallium nitride layer of the substrate. The process vacuum is between 10⁻⁶ and 10⁻¹¹ torr, a flow rate of the nitrogen molecular beam is between 10⁻⁵ and 10⁻⁶ torr, a flow rate of the indium molecular beam is between 1.5x10⁻⁸ and 3.0x10⁻⁸ torr, and a flow rate of the aluminum molecular beam is between 1.0x10⁻⁸ and 2.5x10⁻ ⁸ torr.

It can be seen from the experimental results that when the thin film thickness of the indium aluminum nitride film is about 147 nm, cracks would occur in the thin film if the lattice constant mismatch is greater than 2.4%, and the thin film defects could be reduced if the lattice constant mismatch is less than 1.0%. Moreover, the lattice constant mismatch can be adjusted by controlling the flow rate ratio of the indium molecular beam to the aluminum molecular beam. The flow rate ratio of the indium molecular beam to the aluminum molecular beam are adjusted by temperature control. For example, after the metal molecular beams are heated to a predetermined temperature, a baffle is opened so that the molecular beams are emitted to the surface of the substrate in vapor state.

Further, an indium gallium nitride quantum well can be grown on the indium aluminum nitride film, so that the lattices of the indium gallium nitride quantum well and the lattices of the indium aluminum nitride film match with each other to reduce lattice defects. Among them, the chemical formula of the indium gallium nitride quantum well is InₓGa₁₋ₓN, and the chemical formula of the indium aluminum nitride film is In_{y}Al_{1-y}N. By using Energy-Dispersive X-ray Spectroscopy (EDS) to analyze the composition ratio of the indium gallium nitride quantum well and the indium aluminum nitride film, the values of x and y (less than 1 and greater than 0) can be obtained. The values of x and y represent the indium contents of the indium gallium nitride and in the indium aluminum nitride, respectively. When x ranges from 13.0% to 18.7% and y ranges from 28.9% to 33.5%, the indium gallium nitride quantum well emits blue light; when x ranges from 19.9% to 27.7% and y ranges from 34.6% to 40.9%, the indium gallium nitride quantum well emits green light; and when x ranges from 33.9% to 43.8% and y ranges from 46.0% to 54.1%, the indium gallium nitride quantum well emits red light.

Based on the above, the method for manufacturing an indium gallium nitride quantum well according to the embodiment controls the growth temperature and molecular beam flow rate in the molecular beam epitaxy system, so that the defects are reduced in the formed indium aluminum nitride film, and the quantum well efficiency of the indium gallium nitride quantum well grown subsequently is improved. Furthermore, adjusting the indium contents of the indium aluminum nitride film and the indium gallium nitride quantum well allows the indium gallium nitride quantum well to emit light of different wavelengths, which can be applied to photoelectric components required for various working light wavelengths.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A method for manufacturing an indium gallium nitride quantum well, comprising:
providing a substrate in a process chamber, wherein the substrate includes a gallium nitride layer;
having the process chamber reach a process vacuum;
providing a nitrogen molecular beam in plasma state, an indium molecular beam and an aluminum molecular beam into the process chamber simultaneously, controlling a flow rate ratio of the indium molecular beam to the aluminum molecular beam, and forming an indium aluminum nitride film on the gallium nitride layer, wherein the flow rate ratio is 0.6, 1.0, 1.29, 1.67 or 3.0; and
forming an indium gallium nitride quantum well on the indium aluminum nitride film.

2. The method as claimed in claim 1, wherein the process vacuum is between 10⁻⁶ and 10⁻¹¹ torr.

3. The method as claimed in claim 1, wherein during forming the indium aluminum nitride film, the process chamber is maintained at a growth temperature of 530° C. stably, at a growth vacuum between 10⁻⁵ and 10⁻⁶ torr, and for a duration of 120 minutes.

4. The method as claimed in claim 1, wherein a flow rate of the nitrogen molecular beam is between 10⁻⁵ and 10⁻⁶ torr, a flow rate of the indium molecular beam is between 1.5x10⁻⁸ and 3.0x10⁻⁸ torr, and a flow rate of the aluminum molecular beam is between 1.0x10⁻⁸ and 2.5x10⁻⁸ torr.

5. The method as claimed in claim 1, wherein a chemical formula of the indium gallium nitride quantum well is InₓGa₁₋ₓN, a chemical formula of the indium aluminum nitride film is In_{y}A1_{1-y}N, and values of x and y are analyzed to represent indium contents in the indium gallium nitride quantum well and the indium aluminum nitride film, respectively.

6. The method as claimed in claim 5, wherein the value of x is adjusted between 13.0% to 18.7%, the value of y is adjusted between 28.9% to 33.5%, and the indium gallium nitride quantum well emits blue light.

7. The method as claimed in claim 5, wherein the value of x is adjusted between 19.9% to 27.7%, the value of y is adjusted between 34.6% to 40.9%, and the indium gallium nitride quantum well emits green light.

8. The method as claimed in claim 5, wherein the value of x is adjusted between 33.9% to 43.8%, the value of y is adjusted between 46.0% to 54.1%, and the indium gallium nitride quantum well emits red light.
